(19) United States
(12) Patent Application Publication
(10) Pub. No.: US 2008/0205001 A1
(43) Pub. Date: Aug. 28, 2008

(54) Blower and air conditioner for vehicle

(75) Inventors: Miyuki Saito, Kariya-city (JP); Naoki Uruma, Anjo-city (JP); Kota Ichikawa, Kosai-city (JP)

Correspondence Address: HARNESS, DICKEY & PIERCE, P.L.C., P.O. BOX 828, BLOOMFIELD HILLS, MI, 48303, US

(73) Assignee: DENSO Corporation, Kariya-city (JP)

(21) Appl. No.: 12/008,222

(22) Filed: Jan. 9, 2008

(30) Foreign Application Priority Data
Feb. 26, 2007 (JP) 2007-045080

(51) Int. Cl. H05K 7/20; H02K 5/18

(52) U.S. Cl. 361/697; 310/64

(57) ABSTRACT

A blower includes a casing for defining an air passage through which air is blown into a compartment, a fan located in the casing to generate an air flow in the casing, a motor for driving the fan, a motor control device for controlling a rotation speed of the motor, and a heat sink located to radiate heat of the motor control device to air flowing in the air passage. The heat sink having a radiation fin is exposed into the air passage, and at least one of the motor control device and the heat sink is thermally connected to the yoke of the motor.

### CROSS REFERENCE TO RELATED APPLICATION

This application is based on Japanese Patent Application No. 2007-45080 filed on Feb. 26, 2007, the contents of which are incorporated herein by reference in its entirety.

### BACKGROUND OF THE INVENTION

1. Field of the Invention

The present invention relates to a blower in which a fan is driven by a motor, and an air conditioner for a vehicle using the blower.

2. Description of the Related Art

In a conventional vehicle air conditioner, a motor control device for controlling a motor rotational speed and a heat sink are located in an air-blowing passage so that heat generated from the motor control device is radiated to air in the air-blowing passage via the heat sink. In this case, heat radiation fins of the heat sink need to be increased when the heat generating amount of the motor control device is large. However, when the size of the heat radiation fins of the heat sink is made larger, the air blowing amount may be reduced or air blowing noise may be increased.

JP-A-2004-140893 proposes a motor controller in which heat generated from a motor control device is diffused to a yoke of a motor. In this case, because a cooling capacity for cooling the motor control device is generally small, it is difficult to be used when the motor control device is operated while having a large heat generating amount.

### SUMMARY OF THE INVENTION

In view of the foregoing problems, it is an object of the present invention to effectively cool a motor control device without increasing a radiation fin of a heat sink even when a heat generating amount of the motor control device is large.

It is another object of the present invention to provide a blower and an air conditioner for a vehicle, in which at least one of a motor control device and a heat sink is thermally connected to a yoke of a motor in a structure where the heat sink is located to radiate heat of the motor control device to air flowing in an air passage.

According to an aspect of the present invention, a blower or an air conditioner for a vehicle includes a casing for defining an air passage through which air is blown into a compartment, a fan located in the casing to generate an air flow in the casing, a motor for driving the fan, a motor control device for controlling a rotation speed of the motor, and a heat sink located to radiate heat of the motor control device to air flowing in the air passage. In the air conditioner, the heat sink has a radiation fin exposed into the air passage, and at least one of the motor control device and the heat sink is thermally connected to the yoke of the motor. Accordingly, heat generated in the motor control device can be transmitted and diffused to the yoke while being radiated to air in the air passage via the radiation fin. As a result, heat generated in the motor control device can be effectively radiated even when the size of the radiation fin of the heat sink is made small.

The casing may have therein a motor-cooling air passage part branched from the air passage, and the motor-cooling air passage part may be provided such that a part of air blown by the fan is introduced into an interior of the motor through an outer peripheral side of the yoke. In this case, the motor control device and the heat sink may be located in the motor-cooling air passage part. Accordingly, the motor control device can be also cooled by using air in the motor-cooling air passage part, thereby further increasing heat radiation performance of the motor control device even when the size of the radiation fin is reduced.

The heat sink may be attached onto an outer peripheral surface of the yoke to be stacked with the heat sink in a stack direction. In this case, the heat sink has a dimension in a set direction that is perpendicular to the stack direction and a rotation axis of the motor, and the dimension of the heat sink in the set direction is equal to or smaller than a diameter of the yoke.

In addition, the heat sink may be attached onto the yoke to be fixed to the yoke, and the motor control device may be attached to the heat sink to be fixed to the heat sink. In this case, the motor control device may be fixed to the heat sink at a position closer to the yoke than the air passage, or may be fixed to the heat sink at a position closer to the air passage than the yoke.

A heat conductive sheet may be bonded onto the heat sink. In this case, the heat conductive sheet may be made of a material having a thermal conductivity more than that of the heat sink, and may be attached to transmit heat from the motor control device to the radiation fin of the heat sink.

The heat sink may have another radiation fin that is located to be exposed into the motor-cooling air passage part. In this case, the another radiation fin may include a pair of flat plates arranged in parallel with each other, and the motor control device may be located between the pair of the flat plates.

Alternatively, the heat sink may include a first plate having the radiation fin exposed into the air passage, and a second plate bent from the first plate to contact the yoke. In this case, the motor control device may be attached to the second plate of the heat sink, or may be attached to the first plate of the heat sink. In addition, a heat conductive sheet may be attached onto the heat sink to extend to both the first plate and the second plate of the heat sink. In this case, the motor control device may be attached to one of the first plate and the second plate of the heat sink via the heat conductive sheet.

### BRIEF DESCRIPTION OF THE DRAWINGS

Additional objects and advantages of the present invention will be more readily apparent from the following detailed description of preferred embodiments when taken together with the accompanying drawings. In which:

FIG. 1 is a partial sectional view showing a blower for a vehicle air conditioner according to a first embodiment of the present invention;

FIG. 2 is a perspective view showing a heat sink of the blower in FIG. 1;

FIG. 3 is a partial sectional view showing a blower for a vehicle air conditioner according to a second embodiment of the present invention;

FIG. 4 is a partial sectional view showing a blower for a vehicle air conditioner according to a third embodiment of the present invention;

FIG. 5 is a bottom view showing a motor and a heat sink of a blower for a vehicle air conditioner according to a fourth embodiment of the present invention;

FIG. 6 is a perspective view showing the heat sink of the blower in FIG. 5; and

FIG. 7 is a graph showing a relationship between a width W of the heat sink and a temperature of a semiconductor chip for driving, according to the fourth embodiment.

### DETAILED DESCRIPTION OF THE PREFERRED EMBODIMENTS

### First Embodiment

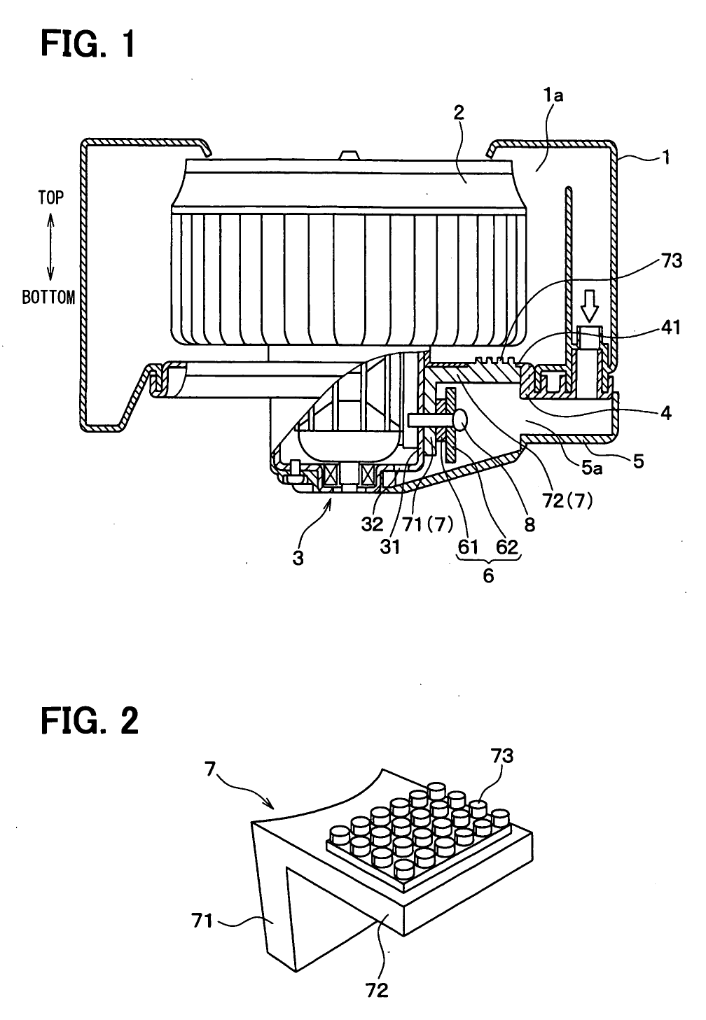

A first embodiment of the present invention will be now described with reference to FIGS. 1 and 2. In the first embodiment, a blower of FIG. 1 is typically used for a vehicle air conditioner.

The vehicle air conditioner includes the blower for blowing air and an air conditioning unit for cooling or/and heating air blown from the blower. The conditioned air of the air conditioning unit is blown into a passenger compartment of the vehicle. The blower is generally located on a front-passenger's seat side adjacent to a driver seat under an instrument panel that is located on the front part of the passenger compartment.

The blower includes a fan casing 1 that is made of resin to form an air passage 1a through which air is blown into the passenger compartment. A fan 2 for generating an air flow in the air passage 1a is located in the fan casing 1. The fan 2 may be made of a resin, for example. The fan 2 includes a plurality of blades around a rotation axis, and is rotated by an electrical motor 3. In the first embodiment, the fan 2 is a centrifugal multi-plate fan in which air is drawn from an axial direction and is blown radially outwardly.

A downstream side of the fan casing 1 is connected to an upstream part of the air conditioning unit (not shown). The air conditioning unit includes an evaporator for cooling air, a heater for heating air from the evaporator, and an air outlet portion located at its downstream side. Therefore, air blown by the fan 2 passes through the evaporator and the heater core so that conditioned air having a set temperature can be obtained. Then, the conditioned air is blown into the passenger compartment through air outlet ports of the air outlet portion.

A resin cover 4 is bonded to an opening portion at one end side of the fan casing 1, and a motor casing 5 made of resin is connected to the resin cover 4. The motor casing 5 has therein a motor-cooling air passage part 5a through which a part of air blown by the fan 2 is introduced to the motor 3. That is, the motor-cooling air passage part 5a is branched from the air passage 1a such that a part of air of the air passage 1a flows into the motor-cooling air passage part 5a.

The motor-cooling air passage part 5a is branched from the air passage 1a, and is formed such that a part of the blown air flows into an interior of the motor 3 via an outer peripheral side of a yoke 31 of the motor 3. The blown air introduced to the motor-cooling air passage part 5a flows into the interior of the motor 3 via through hole 32 of the yoke 31, and returns to the air passage 1a after passing through the interior of the motor 3 (yoke 31).

A motor control device 6 for controlling the rotation speed of the motor 3 and a heat sink 7 for radiating heat of the motor control device 6 to air flowing in the air passage 1a are located in the motor-cooling air passage part 5a. The motor control device 6 and the heat sink 7 are fixed to an outer peripheral side of the yoke 31 by using a screw.

The motor control device 6 includes a semiconductor chip 61 for driving, and a motor control circuit 62 for controlling the semiconductor chip 61 for driving based on instruction signals input from an air conditioning controller (ECU). The semiconductor chip 61 for driving may include a power transistor for supplying and interrupting electrical current applied to the motor 3.

The heat sink 7 may be made of a thermal conductive material such as aluminum or copper, having a relatively high thermal conductivity. Furthermore, the heat sink 7 includes a first plate 71, and a second plate 72 bent from an end of the first plate 71 to be substantially perpendicular to a surface of the first plate 71.

The first plate 71 is attached to the yoke 31 at its surface such that one surface of the first plate 71 tightly contacts one surface of the yoke 31. Furthermore, one surface of the semiconductor chip 61 of the motor control device 6 is tightly attached to the other surface of the first plate 71. The second plate 72 is located approximately parallel to a cover surface of the cover 4, and is exposed to the air passage 1a from an opening portion 41 provided in the cover 4. A plurality of radiation fins 73 are formed on the second plate 72. The second plate 72 is located such that the radiation fins 73 of the second plate 72 protrude into the air passage 1a from the opening portion 41 of the second plate 72 in the air passage 1a.

In the vehicle air conditioner, when the fan 2 is operated by the motor 3, air blown by the fan 2 flows into the air conditioning unit through the air passage 1a. At this time, a part of air blown by the fan 2 is introduced into the motor-cooling air passage 5 so that heat generated in the motor control device 6 is radiated to air introduced into the motor-cooling air passage part 5a.

The heat generated in the motor control device 6 is conducted to the second plate 72 via the first plate 71 of the heat sink 7, and is radiated from the radiation fins 73 of the second plate 72 to air in the air passage 1a. In addition, heat generated in the motor control device 6 is transmitted and diffused to the yoke 31 via the first plate 71 to be radiated.

The heat generated in the motor control device 6 is radiated not only to air in the air passage 1a via the heat sink 7, but also is radiated to air in the motor-cooling air passage part 5a and the yoke 31. Therefore, it is possible to reduce the size of the radiation fins 73 of the heat sink 7. As a result, it can prevent an increase of noise when air is blown by the blower, and can prevent a reduce in the air blowing amount of the blower.

Furthermore, because the size of the radiation fins 73 of the heat sink 7 is reduced, an interference between the first radiation fin 73 and the fan 2 can be easily prevented. Thus, the heat sink 7 can be downsized, thereby the motor control device 6 and the heat sink 7 can be easily arranged in the motor-cooling air passage part 5a.

In the above-described first embodiment, the motor control device 6 is attached to the yoke 31 via the first plate 71 of the heat sink 7 at a position different from the radiation fin 73 of the second plate 72 of the heat sink 7. However, the attachment position of the motor control device 6 is not limited to the position shown in FIG. 1 and may be suitably changed. Furthermore, in FIG. 1, the motor control device 6 is arranged approximately in parallel to the axial direction of the electrical motor 3. However, the motor control device 6 may be arranged to be not parallel to the axial direction of the electrical motor 3 in the heat sink 7 at a position different from the radiation fin 73. In addition, the motor control device 6 may be attached to the heat sink 7 by using a means other than the screw 8 to be thermally connected to the yoke 31 via the heat sink 7.

### Second Embodiment

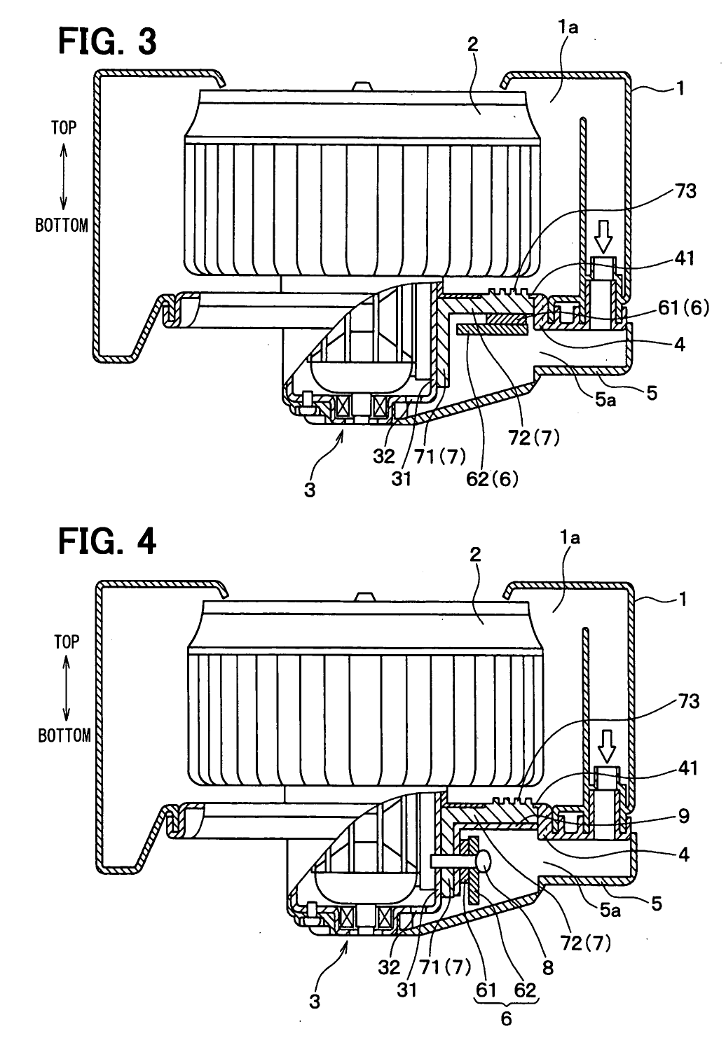

A second embodiment of the present invention will be now described with reference to FIG. 3. In the second embodiment, the position of the motor control device 6, the fixing method of the motor control device 6 and the fixing method of the heat sink 7 are different from those of the above-described first embodiment. In the second embodiment, the parts having the functions as those of the above-described first embodiment are indicated by the same reference numbers, and detail explanation thereof is omitted.

In the second embodiment, as shown in FIG. 3, the motor control device 6 is fixed to the heat sink 7 at a position separated from the yoke 31. That is, the motor control device 6 is connected to the second plate 72 of the heat sink 7, at a position adjacent to the radiation fins 73. Therefore, heat generated in the motor control device 6 can be effectively radiated to air in the air passage 1a via the radiation fins 73 of the heat sink 7. Even in the second embodiment, the motor control device 6 can be thermally connected to the yoke 31 via the heat sink 7, thereby it is possible to radiate heat generated in the motor control device 6 to not only to the air in the air passage 1a and air in the motor-cooling air passage part 5a but also to the yoke 31 via the heat sink 7.

In the second embodiment, the motor control device 6 may be fixed to the heat sink 7 by using an adhesive or a double-stick tape having a good conductivity. Furthermore, the heat sink 7 may be fixed to the yoke 31 by using an adhesive or a double-stick tape having a good conductivity.

### Third Embodiment

A third embodiment of the present invention will be now described with reference to FIG. 4. In the third embodiment, a thermal conductive sheet 9 (heat conductive sheet) is added in the structure of the blower. The other parts having the same functions as those of the above-described first embodiment are indicated by the same reference numbers, and detail explanation thereof is omitted.

The thermal conductive sheet 9 is made of a conductive material having a thermal conductivity more than that of the heat sink 7, and tightly bonded to the thermal conductive sheet 9. The motor control device 6 is attached onto the thermal conductive sheet 9 to be tightly connected to the thermal conductive sheet 9. Therefore, heat generated in the motor control device 6 can be effectively transmitted to the second plate 72 having the radiation fins 73 via the thermal conductive sheet 9. As a result, heat generated in the motor control device 6 can be more effectively radiated not only to air in the air passage 1a via the radiation fins 73, but also to the yoke 32.

The heat sink 7 and the thermal conductive sheet 9 may be made of the same thermal conductive material or different thermal conductive material. For example, in the third embodiment, the heat sink 7 is made of aluminum, and the thermal conductive sheet 9 may be made of copper.

In the third embodiment, the screw 8 is used for fixing the motor control device 6 to the thermal conductive sheet 9. However, the motor control device 6 may be bonded to the thermal conductive sheet 9 by using an adhesive having a thermal conductivity, similarly to the above-described second embodiment. The thermal conductive sheet 9 may be bonded to the heat sink 7 in the structure of FIG. 3. When the motor control device 6 located in the motor-cooling air passage part 5a is thermally connected to the yoke 31 in a structure where the radiation fins 73 of the heat sink 7 are exposed to the air passage 1a, the other structure of the blower may be suitably changed.

### Fourth Embodiment

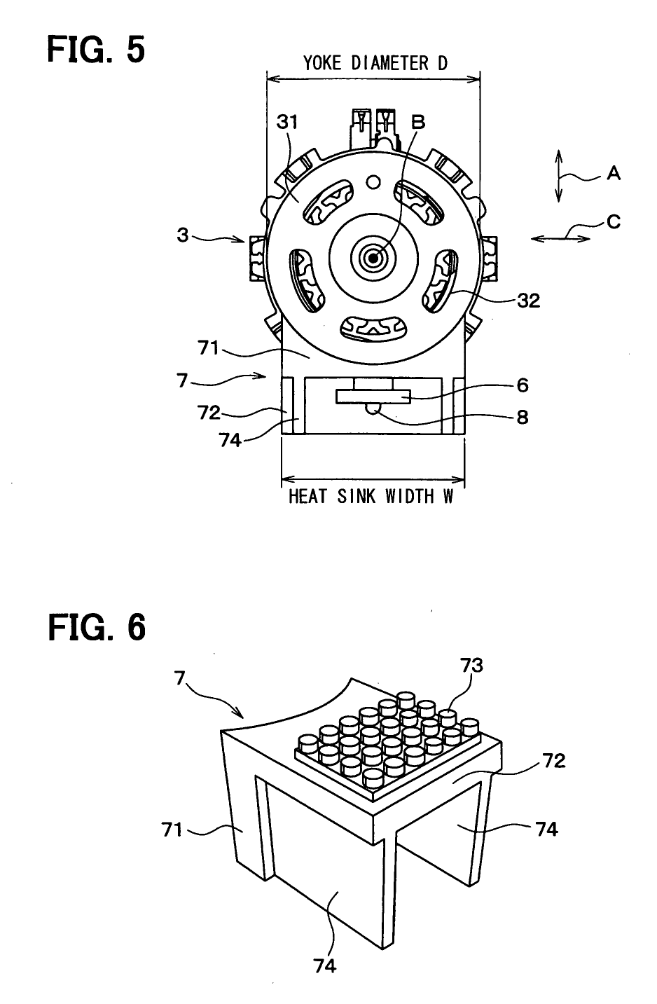

A fourth embodiment will be now described with reference to FIGS. 5 to 7. In the fourth embodiment, a heat sink 7 includes a first plate 71 and a second plate 72. A plurality of first fins 73 are provided on the second plate 72 to be exposed into the air passage 1a, and a pair of second fins 74 are provided to protrude from the first plate 71 and the second plate 72 into the motor-cooling air passage part 5a.

The two second fins 74 are arranged in parallel with each other such that the motor control device 6 is located between the second fins 74. The surfaces of the second radiation fins 74 are arranged approximately in parallel with an air flow direction in the motor-cooling air passage part 5a, thereby reducing a pressure increase in the motor-cooling air passage part 5a.

In the fourth embodiment, because heat generated in the motor control device 6 is also radiated to air in the motor-cooling air passage part 5a from the second radiation fins 74, the heat radiation performance of the heat sink 7 can be more increased.

According to experiments by the inventors of the present application, when the two second radiation fins 74 are provided as in the fourth embodiment, the pressure loss in the motor-cooling air passage part 5a can be reduced as compared with a structure in which a single second radiation fin 74 or plural radiation fins 74 more than two are located. According to the fourth embodiment, the heat radiation performance of the heat sink 7 can be increased while it can prevent a decrease in an air flow amount or an air flow speed in the motor-cooling air passage part 5a.

In FIG. 5, A indicates a stacking direction on which the heat sink 7 and the yoke 31 are stacked, B indicates an axial line direction of the electrical motor 3, and C indicates a width direction (set direction) which is perpendicular to the stacking direction A and the axial line direction B. The heat sink 7 has a width W in the width direction C, and the yoke 31 has a diameter D, as shown in FIG. 5.

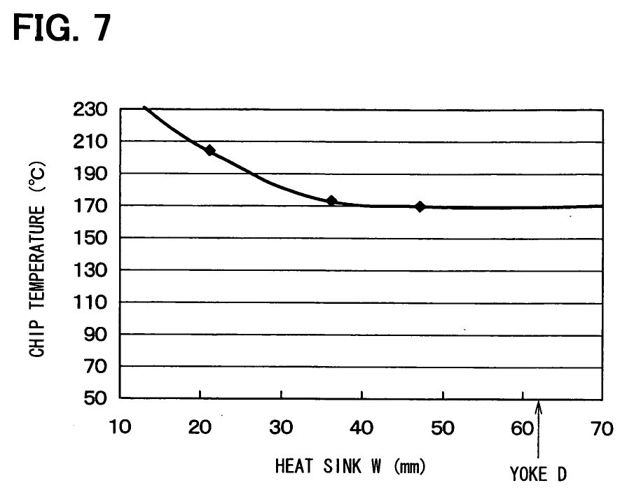

FIG. 7 is a graph showing a relationship between the width W of the heat sink 7 and the temperature (chip temperature) of the semiconductor chip 61. In FIG. 7, the yoke diameter D is set at about 62 mm, and the environment temperature is about 50° C. As shown in FIG. 7, when the width W of the heat sink 7 is equal to or larger than ⅔ of the yoke diameter D, the heat radiation performance of the heat sink 7 can be made approximately constant, thereby the temperature of the semiconductor chip 61 can be set at an approximately constant value.

According to the fourth embodiment of the present invention, by setting the width W of the heat sink 7 in the width direction C to be equal to or lower than the yoke diameter D, the heat radiation performance of the heat sink 7 can be maintained while the size of the heat sink 7 can be effectively reduced.

The structure of the heat sink 7 of the fourth embodiment can be suitably used for one of the blowers described in any one of the first to third embodiments.

### Other Embodiments

Although the present invention has been fully described in connection with the preferred embodiments thereof with reference to the accompanying drawings, it is to be noted that various changes and modifications will become apparent to those skilled in the art.

For example, in the above-described embodiments of the present invention, the one surface of the heat sink 7 is attached onto the yoke 31 so that the motor control device 6 can be thermally connected to the yoke 31 via the heat sink 7. However, one surface of the motor control device 6 may be directly attached onto the yoke 31 so that the motor control device 6 can be thermally connected to the yoke 31, or both the heat sink 7 and the motor control device 6 may be thermally connected to the yoke 31.

In the above-described any embodiments, when the heat sink 7 is located to radiate heat of the motor control device 6 to air flowing in the air passage 1a, and the heat sink 7 has the radiation fins 73 exposed into the air passage 1a, at least one of the motor control device 6 and the heat sink 7 can be thermally connected to the yoke 31 of the motor 3.

In the above-described any embodiments, the heat sink 7 can be attached onto an outer peripheral surface of the yoke 31 to be stacked with the heat sink 7 in the stacking direction A. In this case, the heat sink 7 may have a dimension in the width direction (set direction) that is perpendicular to the stacking direction and the rotation axis direction of the motor 3, and the dimension of the heat sink 7 in the stacking direction may be equal to or smaller than the diameter D of the yoke 31. The heat sink 7 may be attached onto the yoke 31 to be fixed to the yoke 31, and the motor control device 6 may be attached to the heat sink 7 to be fixed to the heat sink 7. In this case, the motor control device 6 may be fixed to the heat sink 7 at a position closer to the yoke 31 than the air passage 1a. Alternatively, the motor control device 6 may be fixed to the heat sink 7 at a position closer to the air passage 1a than the yoke 31.

Furthermore, the heat conductive sheet 9 may be attached onto the heat sink 7. In this case, the heat conductive sheet 9 may be made of a material having a thermal conductivity more than that of the heat sink 7, and may be attached to transmit heat from the motor control device 6 to the radiation fin 73.

In the above-described embodiments, the heat sink 7 with the first and second plates 71, 72 is bent approximately by a right angle. However, the heat sink 7 may be bent by an angle different from the right angle in accordance with the shape of the fan casing 1. In the above-described embodiments, the blower is typically used for a vehicle air conditioner. However, the blower may be used for other air duct for flowing air.

Such changes and modifications are to be understood as being within the scope of the present invention as defined by the appended claims.

What is claimed is:

1. An air conditioner for a vehicle having a passenger compartment, the air conditioner comprising:
a casing for defining an air passage through which air is blown into the passenger compartment;
a fan located in the casing to generate an air flow in the casing;
a motor for driving the fan, the motor having a yoke;
a motor control device for controlling a rotation speed of the motor; and
a heat sink located to radiate heat of the motor control device to air flowing in the air passage, the heat sink having a radiation fin exposed into the air passage,
wherein at least one of the motor control device and the heat sink is thermally connected to the yoke of the motor.

2. The air conditioner according to claim 1, wherein:
the casing has therein a motor-cooling air passage part branched from the air passage, the motor-cooling air passage part being provided such that a part of air blown by the fan is introduced into an interior of the motor through an outer peripheral side of the yoke; and
the motor control device and the heat sink are located in the motor-cooling air passage part.

3. The air conditioner according to claim 2, wherein:
the heat sink is attached onto an outer peripheral surface of the yoke to be stacked with the heat sink in a stack direction;
the heat sink has a dimension in a set direction that is perpendicular to the stack direction and a rotation axis of the motor; and
the dimension of the heat sink in the set direction is equal to or smaller than a diameter of the yoke.

4. The air conditioner according to claim 2, wherein:
the heat sink is attached onto the yoke to be fixed to the yoke; and
the motor control device is attached to the heat sink to be fixed to the heat sink.

5. The air conditioner according to claim 4, wherein the motor control device is fixed to the heat sink at a position closer to the yoke than the air passage.

6. The air conditioner according to claim 4, wherein the motor control device is fixed to the heat sink at a position closer to the air passage than the yoke.

7. The air conditioner according to claim 5, further comprising
a heat conductive sheet bonded onto the heat sink, wherein the heat conductive sheet is made of a material having a thermal conductivity more than that of the heat sink, and is attached to transmit heat from the motor control device to the radiation fin.

8. The air conditioner according to claim 2, wherein:
the heat sink has another radiation fin that is located to be exposed into the motor-cooling air passage part.

9. The air conditioner according to claim 8, wherein:
the another radiation fin includes a pair of flat plates arranged in parallel with each other; and
the motor control device is located between the pair of the flat plates.

10. The air conditioner according to claim 1, wherein:
the heat sink includes a first plate having the radiation fin exposed into the air passage, and a second plate bent from the first plate to contact the yoke; and
the motor control device is attached to the second plate of the heat sink.

11. The air conditioner according to claim 1, wherein:
the heat sink includes a first plate having the radiation fin exposed into the air passage, and a second plate bent from the first plate to contact the yoke; and
the motor control device is attached to the first plate of the heat sink.

12. The air conditioner according to claim 1, wherein the heat sink includes a first plate having the radiation fin exposed into the air passage, and a second plate bent from the first plate to contact the yoke, the air conditioner further comprising
a heat conductive sheet attached onto the heat sink to extend to the first plate and the second plate of the heat sink,
wherein the motor control device is attached to one of the first plate and the second plate of the heat sink via the heat conductive sheet.

13. A blower comprising:
a casing for defining an air passage through which air is blown into a compartment;
a fan located in the casing to generate an air flow in the casing;
a motor for driving the fan, the motor having a yoke;
a motor control device for controlling a rotation speed of the motor; and
a heat sink located to radiate heat of the motor control device to air flowing in the air passage, the heat sink having a radiation fin exposed into the air passage,
wherein at least one of the motor control device and the heat sink is thermally connected to the yoke of the motor.

14. The blower according to claim 13, wherein:
the casing has therein a motor-cooling air passage part branched from the air passage, the motor-cooling air passage part being provided such that a part of air blown by the fan is introduced into an interior of the motor through an outer peripheral side of the yoke; and
the motor control device and the heat sink are located in the motor-cooling air passage part.

15. The blower according to claim 13, wherein:
the heat sink includes a first plate having the radiation fin exposed into the air passage, and a second plate bent from the first plate to contact the yoke; and
the motor control device is attached to the second plate of the heat sink.

16. The blower according to claim 13, wherein:
the heat sink includes a first plate having the radiation fin exposed into the air passage, and a second plate bent from the first plate to contact the yoke; and
the motor control device is attached to the first plate of the heat sink.

17. The blower according to claim 13, wherein the heat sink includes a first plate having the radiation fin exposed into the air passage, and a second plate bent from the first plate to contact the yoke, the blower further comprising
a heat conductive sheet attached onto the heat sink to extend to the first plate and the second plate of the heat sink,
wherein the motor control device is attached to one of the first plate and the second plate of the heat sink via the heat conductive sheet.

18. The blower according to claim 17, wherein the heat conductive sheet is made of a material different from that of the heat sink.

19. The blower according to claim 14, wherein:
the heat sink has another radiation fin that is provided in the second plate to be exposed into the motor-cooling air passage part.

20. The blower according to claim 14, wherein:
the another radiation fin includes a pair of flat plates arranged in parallel with each other; and
the motor control device is located between the pair of the flat plates.
